(19) United States
(12) Patent Application Publication
(10) Pub. No.: US 2021/0378138 A1
(43) Pub. Date: Dec. 2, 2021

(54) MINIATURE HEAT DISSIPATION SYSTEM

(71) Applicant: shih-Rong Wang, Taoyuan City (TW)

(72) Inventor: shih-Rong Wang, Taoyuan City (TW)

(21) Appl. No.: 16/987,355

(22) Filed: Aug. 6, 2020

(30) Foreign Application Priority Data
Jun. 1, 2020 (TW) 109118291

(51) Int. Cl. H05K 7/20; G06F 1/20

(52) U.S. Cl. CPC H05K 7/20209; H05K 7/2039; H05K 7/20172; G06F 1/203

(57) ABSTRACT

A miniature heat dissipation system applicable for a smart communication device includes a sensing module, a heat dissipation module and a control module. The sensing module is disposed on a processing member and detects a temperature of the processing member to generate a first temperature information. The heat dissipation module includes a substrate unit, a rotor unit, a plurality of stator units, and a fan unit. One side of the substrate unit is connected to the sensing module that is located between the processing member and the substrate unit. The rotor unit is disposed on another side of the substrate unit. The plurality of stator units are disposed on the another side of the substrate unit and surround the rotor unit. The fan unit is connected to the rotor unit. The control module is electrically connected to the sensing module and the heat dissipation module.

### CROSS-REFERENCE TO RELATED PATENT APPLICATION

This application claims the benefit of priority to Taiwan Patent Application No. 109118291, filed on Jun. 1, 2020. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a heat dissipation system, and more particularly to a miniature heat dissipation system adapted to an interior of smart communication devices.

### BACKGROUND OF THE DISCLOSURE

With the progression of technology, exterior design of electronic devices (such as laptops, tablet computers or smartphones) has developed toward being lighter, thinner, shorter, and smaller so as to reduce the space taken up by the electronic devices and allow users to conveniently carry the electronic devices.

The electronic devices generally generate heat during operation. Therefore, a fan disposed inside a computer has been developed to blow out hot air generated from the operation of the computer or blow cold air to a heat source to aid heat dissipation and help maintain the overall heat dissipation effect. However, due to a limited interior space of a common mobile phone, it is difficult for the fan to be disposed therein, and the heat dissipation by air circulation cannot be provided.

In addition, existing fans are designed to operate when the electronic devices are turned on and in operation. Only when the electronic device is turned off will the fan stop operating, which can easily lead to excessive power consumption of the electronic devices, so that the user is required to frequently charge the electronic devices.

Moreover, since coils are wound around a rotor of a motor of a conventional fan, an overall weight of the rotor can easily be imbalanced to cause a shift in the center of gravity of the rotor, and in turn causing the rotor to be off-centered during rotation due to an inability to keep balance.

Therefore, how the abovementioned deficiencies of conventional fans can be overcome has become an important issue in this field.

### SUMMARY OF THE DISCLOSURE

In response to the above-referenced technical inadequacies, the present disclosure provides a miniature heat dissipation system applicable to mobile devices such as mobile phones or tablets. The miniature heat dissipation system of the present disclosure has a lightweight and thin structure, and is capable of being disposed directly in a casing of the mobile device to provide heat dissipation by air circulation to microprocessors therein, such as a microprocessor, a central processing unit (CPU) and like components.

In one aspect, the present disclosure provides a miniature heat dissipation system adapted to a smart communication device. The smart communication device includes a housing member and a processing member, and the processing member is located in the housing member. The miniature heat dissipation system includes a sensing module, a heat dissipation module, and a control module. The aforementioned smart communication device may be, but is not limited to, mobile devices such as mobile phones or tablets. The sensing module is disposed on the processing member, and the sensing module detects a temperature of the processing member to generate a first temperature information. The heat dissipation module includes a substrate unit, a rotor unit, a plurality of stator units, and a fan unit. One side of the substrate unit is connected to the sensing module, and the sensing module is located between the processing member and the substrate unit. The rotor unit is disposed on another side of the substrate unit. The plurality of stator units are disposed on the another side of the substrate unit, and the plurality of stator units surround the rotor unit. The fan unit is connected to the rotor unit. The control module is electrically connected to the sensing module and the heat dissipation module. When the control module receives the first temperature information and determines that the first temperature information exceeds a temperature threshold, the control module provides power to the plurality of stator units and drives the fan unit to perform heat dissipation for the processing member.

Therefore, by virtue of “the sensing module is disposed on the processing member, and the sensing module detects a temperature of the processing member to generate a first temperature information”, “the heat dissipation module includes a substrate unit, a rotor unit, a plurality of stator units, and a fan unit”, “one side of the substrate unit is connected to the sensing module, and the sensing module is located between the processing member and the substrate unit”, “the rotor unit is disposed on another side of the substrate unit”, “the plurality of stator units are disposed on the another side of the substrate unit, and the plurality of stator units surround the rotor unit”, “the fan unit is connected to the rotor unit”, and “the control module is electrically connected to the sensing module and the heat dissipation module, and when the control module receives the first temperature information and determines that the first temperature information exceeds the temperature threshold, the control module provides power to the plurality of stator units and drives the fan unit to perform heat dissipation for the processing member”, the miniature heat dissipation system provided by the present disclosure can achieve an effect of heat dissipation, and resolve the issue of conventional rotors being off-centered easily.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is an exploded view of a miniature heat dissipation system according to a first embodiment of the present disclosure.

FIG. 2 is an exploded schematic view of a heat dissipation module of the miniature heat dissipation system according to the first embodiment of the present disclosure.

FIG. 3 is a partial sectional schematic view of the miniature heat dissipation system according to the first embodiment of the present disclosure.

FIG. 4 is a functional block diagram of the miniature heat dissipation system according to the first embodiment of the present disclosure.

FIG. 5 is a cross-sectional schematic view of a miniature heat dissipation system according to a second embodiment of the present disclosure.

FIG. 6 is a perspective view of a miniature heat dissipation system according to a third embodiment of the present disclosure.

FIG. 7 is a functional block diagram of the miniature heat dissipation system according to the third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

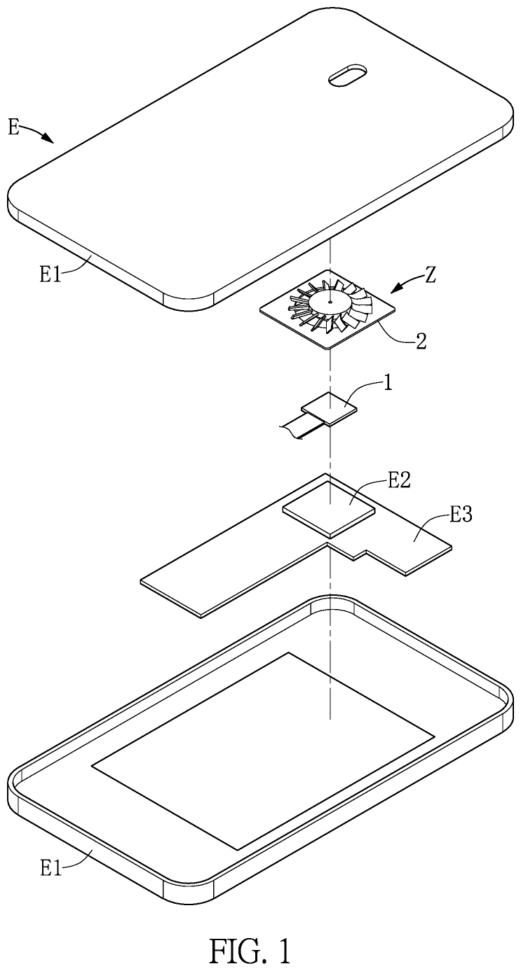

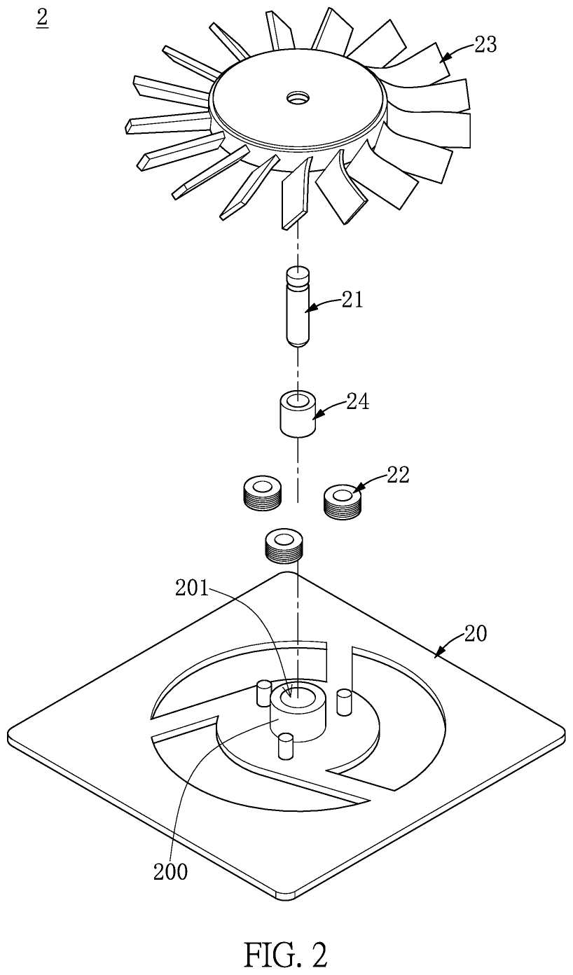

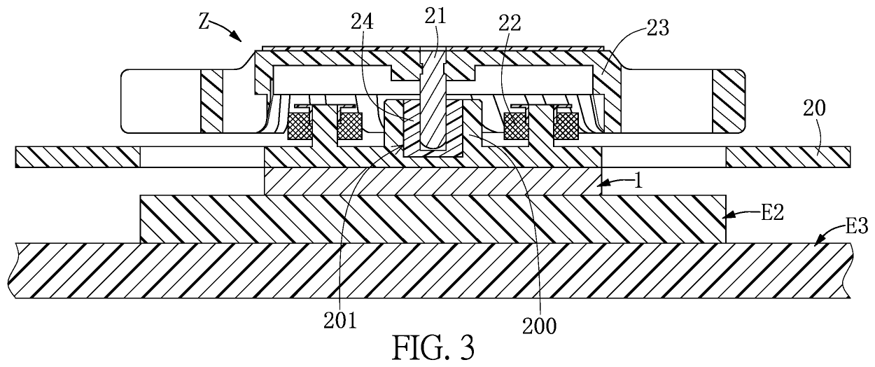

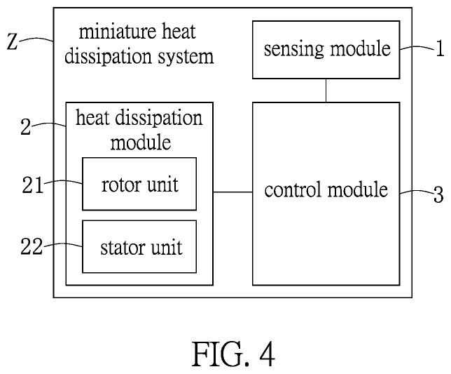

References are made to FIG. 1 to FIG. 4, which are respectively an exploded view, an exploded schematic view of a cooling module, a partially sectional schematic view, and a functional block diagram of a miniature heat dissipation system according to a first embodiment of the present disclosure. As shown in the figures, the first embodiment of the present disclosure provides a miniature heat dissipation system Z adapted to a smart communication device E. The smart communication device E includes a housing member E1 and a processing member E2 that is located in the housing member E1. The miniature heat dissipation system Z includes a sensing module 1, a heat dissipation module 2, and a control module 3. The sensing module 1 is disposed on the processing member E2, and the sensing module 1 detects the temperature of the processing member E2 to generate a first temperature information. The heat dissipation module 2 includes a substrate unit 20, a rotor unit 21, a plurality of stator units 22, and a fan unit 23. One side of the substrate unit 20 is connected to the sensing module 1, and the sensing module 1 is located between the processing member E2 and the substrate unit 20. The rotor unit 21 is disposed on another side of the substrate unit 20. The plurality of stator units 22 are disposed on the another side of the substrate unit 20, and the plurality of stator units 22 surround the rotor unit 21. The fan unit 23 is connected to the rotor unit 21. The control module 3 is electrically connected to the sensing module 1 and the heat dissipation module 2. When the control module 3 receives the first temperature information and determines that the first temperature information exceeds a temperature threshold, the control module 3 will then provide power to the plurality of stator units 22 and drive the fan unit 23 to perform heat dissipation for the processing member E2. As shown in the figures, the stator units 22 are coil windings, the quantity of the stator units 22 may be three, and the three stator units 22 are disposed directly below the fan and fixedly arranged on the substrate unit 20. The three stator units 22 are arranged to form the shape of a regular triangle where distances between any two of the three stator units 22 are the same. Magnetic fields generated by the rotor 21 and the stator units 22 interact with each other and generate a driving force that drives the fan unit 23 to operate. In one embodiment of the present disclosure, the fan unit 23 may have magnets directly disposed thereon so as to generate a driving force by interacting with the magnetic fields generated by the stator units 22, and the present disclosure is not limited thereto.

Specifically, the miniature heat dissipation system Z provided by the present disclosure is adapted to perform heat dissipation for an interior of the smart communication device E. The smart communication device E may be a smartphone, but it is not limited thereto. The miniature heat dissipation system Z of the present disclosure includes the sensing module 1, the heat dissipation module 2, and the control module 3. The sensing module 1 can be a cooling chip or a thermosensitive resistor, and the control module 3 can be a microprocessor, but they are not limited thereto in the present disclosure. The sensing module 1 is disposed on one side of the processing member E2 of the smart communication device E, and another side of the processing member E2 can be connected to a circuit E3. The heat dissipation module 2 includes the substrate unit 20, the rotor unit 21, the plurality of stator units 22, and the fan unit 23. The substrate unit 20 may be a metal plate, and the plurality of stator units 22 may be coil windings. The plurality of stator units 22 may be disposed on the substrate unit 20 at an equal distance from each other, and the plurality of stator units 22 may form a ring shape, but they are not limited thereto. The rotor unit 21 may be an axis member made of a metal or a magnetic material. Further, overall precision and weight of the rotor unit 21 of the present disclosure are achieved by undergoing special adjustment and manufacturing process, thereby enabling the rotor unit 21 to have features such as an evenly distributed weight and a balanced structure. Therefore, a center of gravity of the rotor unit 21 is located on a central axis of the rotor unit 21. An end of the rotor unit 21 is connected to the fan unit 23, another end of the rotor unit 21 is rotatably connected to the substrate unit 20, and the rotor unit 21 is surrounded by the plurality of stator units 22. A body of the fan unit 23 may be made of a magnetic material and a plastic material, or only a plastic material, blades of the fan unit 23 may be made of a plastic material, and a thickness of the fan unit 23 may be between 0.2 and 0.5 millimeters. The control module 3 is electrically connected to the sensing module 1 and the plurality of stator units 22.

Therefore, the miniature heat dissipation system Z of the present disclosure may detect, by the sensing module 1, a temperature of the processing member E2 during operation thereof, and correspondingly generate one or a plurality of temperature information. For example, when the sensing module 1 is a cooling chip, the sensing module 1 may generate a first temperature information (such as a voltage) according to a difference between a cold surface and a hot surface. After the control module 3 receives the first temperature information, the first temperature information acquired by the control module 3 may be, for example, a temperature information of a difference of 36° C.; moreover, after the control module 3 determines that the 36° C. exceeds a temperature threshold of 35° C., the control module 3 provides power to the plurality of stator units 22 and drives the fan unit 23 to rotate, so as to perform heat dissipation for the processing member E2.

Therefore, by the aforementioned technical solutions, only when an operating temperature of the processing member E2 reaches a certain value will the miniature heat dissipation system Z of the present disclosure actuate the heat dissipation module 2 to perform heat dissipation for the processing member E2, thereby achieving an energy-saving effect. Furthermore, by disposing the rotor unit 21 with an evenly distributed weight and a balanced structure, the rotor unit 21 can achieve a balancing effect when rotating, thereby allowing the miniature heat dissipation system Z of the present disclosure to resolve an issue of a rotor of a conventional motor being easily off-centered during rotation.

Furthermore, when the heat dissipation module 2 performs heat dissipation and the control module 3 determines a second temperature information to be equal to or less than the temperature threshold, the control module 3 stops providing the power to the plurality of stator units 22 so as to stop the fan unit 23 from rotating. For example, when the sensing module 1 detects a temperature of the processing member E2 during operation thereof and generates a plurality of temperature information, and when the control module 3 determines that the second temperature information generated by the sensing module 1 is not greater than the temperature threshold, the control module 3 does not provide the power to the plurality of stator units 22, or the control module 3 stops providing the power to the rotor unit 21. That is to say, when the heat dissipation module 2 performs heat dissipation and the control module 3 determines that the second temperature information provided by the sensing module 1 is not greater than the temperature threshold, the control module 3 stops providing the power to the plurality of stator units 22 such that the fan unit 23 stops rotating, and then stops performing heat dissipation for the processing member E2.

Further, the temperature threshold may include a first predetermined threshold and a second predetermined threshold. After the control module 3 determines that the first temperature information is greater than the first predetermined threshold and less than the second predetermined threshold, the control module 3 drives the fan unit 23 to rotate at a first predetermined rotational speed. When the control module 3 determines that the first temperature information is greater than or equal to the second predetermined threshold, the control module 3 drives the fan unit 23 to rotate at a second predetermined rotational speed.

For example, the control module 3 may have a plurality of built-in predetermined threshold parameters, such as the first predetermined threshold being 35° C., and the second predetermined threshold being 45° C. Therefore, when the control module 3 receives the first temperature information of 36° C., the control module 3 may provide power (such as a first voltage) to the plurality of stator units 22 and drive the fan unit 23 to rotate at a first predetermined rotational speed, and the first predetermined rotational speed may be between 2000 and 2500 revolutions per minute, but it is not limited thereto. When the control module 3 receives the first temperature information of 46° C., the temperature of the processing member E2 has exceeded the second predetermined threshold. At this time, the control module 3 may provide power (such as a second voltage) to the plurality of stator units 22 and drive the fan unit 23 to rotate at a second predetermined rotational speed, and the second predetermined rotational speed may be between 3500 and 4500 revolutions per minute, with a voltage value of the second voltage being greater than a voltage value of the first voltage, but it is not limited thereto.

Furthermore, the another side of the substrate unit 20 of the present disclosure can protrude outwards to form a protrusion 200, and the protrusion 200 has a recess 201. In addition, the heat dissipation module 2 may include a limiting unit 24, and the limiting unit 24 may be of a hollow structure. The limiting unit 24 may be a bearing or a sleeve, but it is not limited thereto. The limiting unit 24 may be disposed in the recess 201, and the rotor unit 21 is arranged to rotatably penetrate the limiting unit 24. Therefore, by a cooperation of the rotor unit 21 and the limiting unit 24, the miniature heat dissipation system Z of the present disclosure can further improve the balance and the stability of the rotor unit 21 during rotation.

It should be noted that, the control module 3 of the present disclosure may have a built-in temperature reference table, so that when the control module 3 receives the first temperature information, the control module 3 obtains related temperature data or parameters based on the temperature reference table. Furthermore, temperature parameters and parameters of the predetermined rotational speed of the rotor unit 21 in the aforementioned embodiments are only exemplifications. During an actual application of the miniature heat dissipation system Z of the present disclosure, values of the temperature threshold and the predetermined rotational speed may be set by a user or a manufacturer.

The aforementioned examples are only one of the feasible implementations of the present disclosure, and the present disclosure is not intended to be limited thereto.

### Second Embodiment

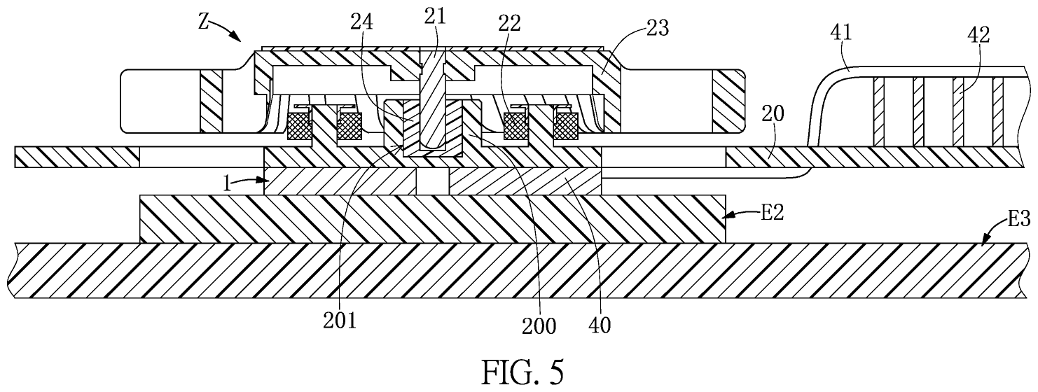

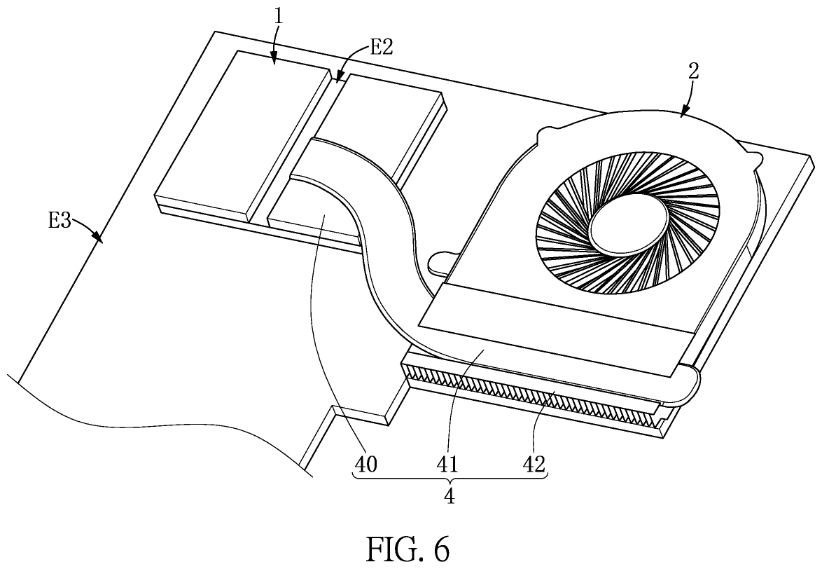

References are made to FIG. 5 and FIG. 6, which are a cross-sectional schematic view and a perspective schematic view of the miniature heat dissipation system Z of the present disclosure, and are to be viewed in conjunction with FIG. 1 to FIG. 4. As shown in the figures, components of a miniature heat dissipation system of the present embodiment have similar manners of operation with the same components of the miniature heat dissipation system of the aforementioned first embodiment, and will not be reiterated herein. It should be noted that, in the present embodiment, the miniature heat dissipation system Z further includes a heat conduction module 4, and the heat conduction module 4 includes a heat absorption unit 40, a heat pipe unit 41, and a heat releasing unit 42. The heat absorption unit 40 is disposed on the processing member E2. One end of the heat pipe unit 41 is connected to the heat absorption unit 40. The heat releasing unit 42 is connected to another end of the heat pipe unit 41. The heat absorption unit 40 absorbs heat of the processing member E2, the heat pipe unit 41 transmits the heat to the heat releasing unit 42, and the heat releasing unit 42 releases the heat to the outside.

For example, in conjunction with FIG. 5, the miniature heat dissipation system Z of the present disclosure may further include the heat conduction module 4, and the heat conduction module 4 includes the heat absorption unit 40, the heat pipe unit 41, and the heat releasing unit 42. The heat absorption unit 40 may be a metal block or a metal plate that is capable of absorbing heat, the heat pipe unit 41 may be a planar heat pipe or a flat heat pipe, and the heat releasing unit 42 may be a heat dissipation fin, but it is not limited thereto. Therefore, the miniature heat dissipation system Z of the present disclosure absorbs heat of the processing member E2 through the heat absorption unit 40, utilizes the heat pipe unit 41 to transmit the heat to the heat releasing unit 42, and releases the heat to the outside by the heat releasing unit 42. When the heat conduction module 4 cannot completely dissipate the heat of the processing member E2, the miniature heat dissipation system Z can use the heat dissipation module 2 as a back-up heat dissipation mechanism to dissipate heat for the processing member E2. The timing for actuating and turning off the heat dissipation module 2 is the same as that described in the first embodiment, and will not be reiterated herein.

Furthermore, the miniature heat dissipation system Z of the present disclosure may improve a heat dissipation speed of the heat conduction module 4 by a cooperation of the heat dissipation module 2 and the heat conduction module 4. For example, in conjunction with FIG. 6, the miniature heat dissipation system Z of the present disclosure may have an exhaust opening of the heat dissipation module 2 arranged to be corresponding to the heat releasing unit 42. Therefore, when the heat of the processing member E2 is transmitted to the heat releasing unit 42, the heat dissipation module 2 can be used to generate airflow toward the heat releasing unit 42, so that a heat dissipation speed of the heat releasing unit 42 is improved.

The aforementioned examples are only one of feasible implementations of the present disclosure, and the present disclosure is not intended to be limited thereto.

### Third Embodiment

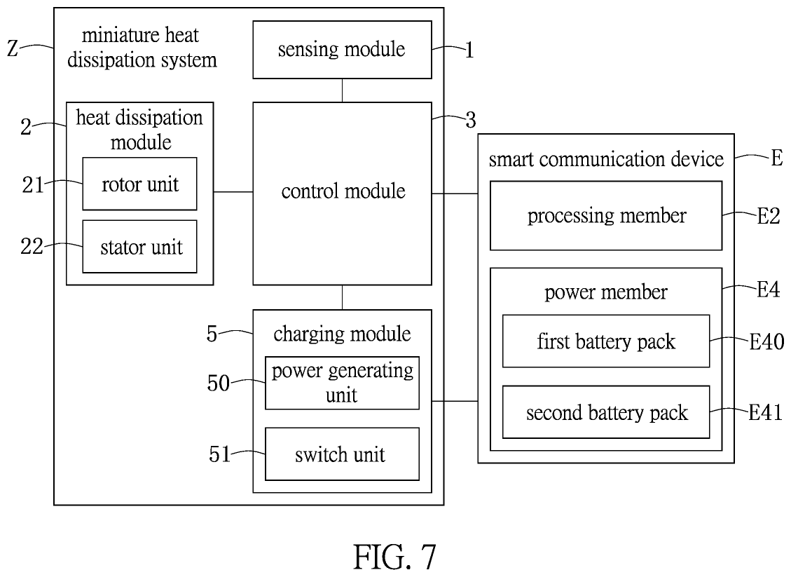

Reference is made to FIG. 7, which is a functional block diagram of the miniature heat dissipation system according to the third embodiment of the present disclosure, and viewed in conjunction with FIG. 1 to FIG. 6. As shown in the figures, components of a miniature heat dissipation system of the present embodiment have similar manners of operation with the same components of the miniature heat dissipation system of the aforementioned embodiments, and will not be reiterated herein. It should be noted that, in the present embodiment, the miniature heat dissipation system Z further includes a charging module 5, and the charging module 5 includes a plurality of power generating units 50 that are disposed on the another side of the substrate unit 20 and surround the rotor unit 21. The plurality of power generating units 50 are electrically connected to the control module 3 and a power member E4 of the smart communication device E, the plurality of power generating units 50 generate power by rotation of the rotor unit 21, and the plurality of power generating units 50 provide the power to the power member E4.

For example, the miniature heat dissipation system Z further includes a charging module 5, and the charging module 5 includes a plurality of power generating units 50. The plurality of power generating units 50 can be power-generating coil windings. Each of the plurality of power generating units 50 may be disposed between two of the stator units 22, but it is not limited thereto. Therefore, when the rotor unit 21 rotates, the plurality of power generating units 50 may generate the power by the operation of the rotor unit 21 or the fan unit 23, and transmit the power to the power member E4 of the smart communication device E for storage.

Furthermore, the charging module 5 may further include a switch unit 51.

The switch unit 51 is electrically connected to the plurality of power generating units 50, the control module 3, and the power member E4. The control module 3 is electrically connected to the processing member E2. When the control module 3 receives a low power information from the processing member E2, the control module 3 drives the switch unit 51 to be in a turned-on state, so that the plurality of power generating units 50 provide the power to the power member E4. When the control module 3 receives high power information from the processing member E2, the control module 3 drives the switch unit 51 to switch from the turned-on state to a turned-off state.

For example, the charging module 5 of the present disclosure may further include the switch unit 51 that is located between the plurality of power generating units 50 and the power member E4, and is electrically connected to the control module 3. In addition, the control module 3 can be electrically connected to the processing member E2. Therefore, when the control module 3 receives the low power information from the processing member E2, such as when the power member E4 has less than 70% of charge, the processing member E2 sends the low power information to the control module 3. At this time, the control module 3 may drive the switch unit 51 to switch from the turned-off state to the turned-on state. Then, when the plurality of power generating units 50 generate the power, the power can be provided to the power member E4.

Conversely, when the control module 3 receives the high power information from the processing member E2, such as when the power member E4 has more than 80% of charge, the processing member E2 sends the high power information to the control module 3. At this time, the control module 3 may drive the switch unit 51 to switch from the turned-on state to the turned-off state. Therefore, when the plurality of power generating units 50 generate the power, the power cannot be provided to the power member E4.

Furthermore, the control module 3 is electrically connected to a first battery pack E40 of the power member E4, and the switch unit 51 is electrically connected to a second battery pack E41 of the power member E4. For example, the power member E4 of the smart communication device E may include the first battery pack E40 and the second battery pack E41 that are electrically connected to each other. Furthermore, the control module 3 may be electrically connected to the first battery pack E40 of the power member E4, and the charging module 5 may be electrically connected to the second battery pack E41 of the power member E4. Therefore, the miniature heat dissipation system Z of the present disclosure may provide the power to the heat dissipation module 2 and the control module 3 by the first battery pack E40, and the miniature heat dissipation system Z may also use the charging module 5 to generate the power and provide the power to the second battery pack E41.

The aforementioned examples are only one of the feasible implementations of the present disclosure, and the present disclosure is not intended to be limited thereto.

### Advantageous Effects of the Embodiments

One of the advantageous effects of the present disclosure is, by virtue of “the sensing module 1 is disposed on the processing member E2, and the sensing module 1 detects the temperature of the processing member E2 to generate the first temperature information”, “the heat dissipation module 2 includes a substrate unit 20, a rotor unit 21, a plurality of stator units 22, and a fan unit 23”, “one side of the substrate unit 20 is connected to the sensing module 1, and the sensing module 1 is located between the processing member E2 and the substrate unit 20”, “the rotor unit 21 is disposed on the another side of the substrate unit 20”, “the plurality of stator units 22 are disposed on the another side of the substrate unit 20, and the plurality of stator units 22 surround the rotor unit 21”, “the fan unit 23 is connected to the rotor unit 21”, and “the control module 3 is electrically connected to the sensing module 1 and the heat dissipation module 2, and when the control module 3 receives the first temperature information and determines that the first temperature information exceeds a temperature threshold, the control module 3 provides power to the plurality of stator units 22 to prompt the rotor unit 21 to rotate, and further drives the fan unit 23 to perform heat dissipation for the processing member E2”, the miniature heat dissipation system provided by the present disclosure can achieve the effect of energy-saving, and resolve the issue of conventional rotors being off-centered easily.

Furthermore, by the aforementioned technical solutions, only when an operating temperature of the processing member E2 reaches a certain value will the miniature heat dissipation system Z of the present disclosure actuate the heat dissipation module 2 to perform heat dissipation for the processing member E2, thereby achieving an energy-saving effect. Furthermore, by disposing the rotor unit 21 with an evenly distributed weight and a balanced structure, the rotor unit 21 can achieve a balancing effect when rotating, thereby allowing the miniature heat dissipation system Z of the present disclosure to resolve an issue of a rotor of a conventional motor being easily off-centered during rotation, thereby resolving issues of a rotor of a conventional motor being easily off-centered due to uneven weight distribution and inability to have a balanced rotation. Furthermore, the miniature heat dissipation system Z of the present disclosure increases heat dissipation efficiency by the cooperation of the heat conduction module 4 and the heat dissipation module 2. Further yet, by using the charging module 5, the miniature heat dissipation system Z of the present disclosure improves the endurance of the smart communication device E.

In conclusion, the miniature heat dissipation system Z of the present disclosure can be integrated into mobile devices such as a mobile phone to solve a heat dissipation issue of the mobile phone. The miniature heat dissipation system Z of the present disclosure has a lightweight and thin structure, and can be disposed in a casing of the mobile phone, while a battery of the mobile phone provides power to the miniature heat dissipation system Z. The miniature heat dissipation system Z may adjust a rotational speed of a fan according to a temperature sensed thereby to achieve a better heat dissipation effect and save power. Furthermore, the miniature heat dissipation system Z can reversely charge the battery of the mobile phone, thereby extending a use time thereof.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A miniature heat dissipation system adapted to a smart communication device, the smart communication device including a housing member and a processing member located in the housing member, the miniature heat dissipation system comprising:
a sensing module being disposed on the processing member, wherein the sensing module detects a temperature of the processing member to generate a first temperature information;
a heat dissipation module, including:
a substrate unit, wherein one side of the substrate unit is connected to the sensing module, and the sensing module is located between the processing member and the substrate unit;
a rotor unit being disposed on another side of the substrate unit;
a plurality of stator units being disposed on the another side of the substrate unit, wherein the plurality of stator units surround the rotor unit; and
a fan unit being connected to the rotor unit; and
a control module being electrically connected to the sensing module and the heat dissipation module, wherein when the control module receives the first temperature information and determines that the first temperature information exceeds a temperature threshold, the control module provides power to the plurality of stator units and drives the fan unit to perform heat dissipation for the processing member.

2. The miniature heat dissipation system according to claim 1, wherein when the heat dissipation module performs heat dissipation and the control module determines that a second temperature information is equal to or less than the temperature threshold, the control module stops providing power to the plurality of stator units such that the fan unit stops rotating.

3. The miniature heat dissipation system according to claim 1, wherein the temperature threshold includes a first predetermined threshold and a second predetermined threshold, and when the control module determines that the first temperature information is greater than the first predetermined threshold and less than the second predetermined threshold, the control module drives the fan unit to rotate at a first predetermined rotational speed.

4. The miniature heat dissipation system according to claim 3, wherein when the control module determines that the first temperature information is greater than or equal to the second predetermined threshold, the control module drives the fan unit to rotate at a second predetermined rotational speed.

5. The miniature heat dissipation system according to claim 1, further comprising a heat conduction module, the heat conduction module including:
a heat absorption unit being disposed on the processing member;
a heat pipe unit, wherein one end of the heat pipe unit is connected to the heat absorption unit; and
a heat releasing unit being connected to another end of the heat pipe unit;
wherein the heat absorption unit absorbs heat of the processing member and utilizes the heat pipe unit to transmit the heat to the heat releasing unit, and the heat releasing unit releases the heat to the outside.

6. The miniature heat dissipation system according to claim 1, wherein the heat pipe unit is a planar heat pipe or a flat heat pipe.

7. The miniature heat dissipation system according to claim 1, further comprising a charging module, wherein the charging module includes a plurality of power generating units that are disposed on the another side of the substrate unit and surround the rotor unit, the plurality of power generating units are electrically connected to the control module and a power member of the smart communication device, the plurality of power generating units generate power by rotation of the rotor unit or the fan unit, and the plurality of power generating units provide the power to the power member.

8. The miniature heat dissipation system according to claim 7, wherein the charging module further includes a switch unit, the switch unit is electrically connected to the plurality of power generating units, the control module and the power member; wherein the control module is electrically connected to the processing member; wherein when the control module receives a low power information from the processing member, the control module drives the switch unit to be in a turned-on state, so that the plurality of power generating units provide the power to the power member.

9. The miniature heat dissipation system according to claim 8, wherein when the control module receives a high power information from the processing member, the control module drives the switch unit to switch from the turned-on state to a turned-off state.

10. The miniature heat dissipation system according to claim 7, wherein the control module is electrically connected to a first battery pack of the power member, and the switch unit is electrically connected to a second battery pack of the power member.
